(19) United States
(12) Patent Application Publication
(10) Pub. No.: US 2010/0248429 A1
(43) Pub. Date: Sep. 30, 2010

(54) METHOD FOR MANUFACTURING SEMICONDUCTOR MODULES

(76) Inventors: Yoshio OKAYAMA, Osaka (JP); Katsumi Ito, Osaka (JP)

Correspondence Address: MCDERMOTT WILL & EMERY LLP, 600 13TH STREET, N.W., WASHINGTON, DC, 20005-3096, US

(21) Appl. No.: 12/727,749

(22) Filed: Mar. 19, 2010

(30) Foreign Application Priority Data
Mar. 31, 2009 (JP) 2009-086621

(51) Int. Cl. H01L 21/60

(52) U.S. Cl. 438/121; 257/E21.506

(57) ABSTRACT

In a method for making a semiconductor module, a bump electrode and a recess are formed by etching a copper sheet. An insulating resin layer is formed, in the recess, up to a position lower than the height of the bump electrode, and then a semiconductor device and the copper sheet, including a wiring layer formed integrally with the bump electrode, are press-bonded together. The wiring layer is warped to protrude toward the semiconductor device, which assures the electrical connection between the bump electrodes and device electrodes.

### CROSS-REFERENCE TO RELATED APPLICATIONS

This application is based upon and claims the benefit of priority from the prior Japanese Patent Applications No. 2009-086621, filed on Mar. 31, 2009, the entire contents of which are incorporated herein by reference.

### BACKGROUND OF THE INVENTION

1. Field of the Invention

The present invention relates to a method for manufacturing semiconductor modules.

2. Description of the Related Art

In recent years, with miniaturization and higher performance in electronic devices, demand has been ever greater for further miniaturization of semiconductor modules used in the electronic devices. To realize this, it is of absolute necessity that the pitch of external connection electrodes of the semiconductor module be made narrower. However, there are restrictive factors for the narrowing of the pitch of external connection electrodes, such as the size of the solder ball itself and the bridge formation at soldering. Recently, to overcome these limitations, the external connection electrodes are rearranged by forming the rewiring in the semiconductor module. As one method used for such rearrangement, known is a method, for example, where a bump structure formed by half-etching a silicon substrate is used as an electrode or a via, and the external connection electrodes of the semiconductor module are connected to the bump structure by mounting a semiconductor chip on the silicon substrate with an insulating layer, such as epoxy resin, held between the semiconductor chip and the silicon substrate.

However, a space between the silicon substrate having the bump structure and the semiconductor chip is filled with an insulating layer therebetween. Thus insulating materials flow into such spaces and part of the insulating layer remains there. As a result, a faulty electrical connection may occur between the silicon substrate and the semiconductor chip.

### SUMMARY OF THE INVENTION

A method, for manufacturing a semiconductor module, according to one embodiment of the present invention comprises: a first process of forming a protrusion by etching a metallic sheet; a second process of forming an insulating layer having a thickness such that the protrusion is partially exposed; and a third process of press-bonding a semiconductor substrate, having a plurality of electrodes on the surface thereof, and the metallic sheet via the insulating layer and electrically connecting the protrusion to the electrode.

By employing this embodiment, the electrical connection between bump electrodes and device electrodes is assured.

### BRIEF DESCRIPTION OF THE DRAWINGS

Embodiments will now be described by way of examples only, with reference to the accompanying drawings which are meant to be exemplary, not limiting and wherein like elements are numbered alike in several Figures in which:

FIG. 1 is a cross-sectional view showing a structure of a semiconductor module according to a first embodiment of the present invention;

FIG. 2 is a plan view showing a structure of a semiconductor module according to a first embodiment of the present invention;

FIGS. 3A to 3H are cross-sectional views, taken along the line A-A′ of FIG. 2, showing a process in a method for making a semiconductor module according to a first embodiment of the present invention;

FIGS. 4A to 4C are cross-sectional views, taken along the line A-A′ of FIG. 2, showing a process in a method for making a semiconductor module according to a first embodiment of the present invention;

FIGS. 5A to 5E are cross-sectional views, taken along the line A-A′ of FIG. 2, showing a process in a method for making a semiconductor module according to a first embodiment of the present invention; and

FIGS. 6A to 6C are cross-sectional views, taken along the line A-A′ of FIG. 2, showing a process in a method for making a semiconductor module according to a second embodiment of the present invention.

### DETAILED DESCRIPTION OF THE INVENTION

The invention will now be described by reference to the preferred embodiments. This does not intend to limit the scope of the present invention, but to exemplify the invention.

Hereinbelow, the embodiments will be described with reference to the accompanying drawings.

### First Embodiment

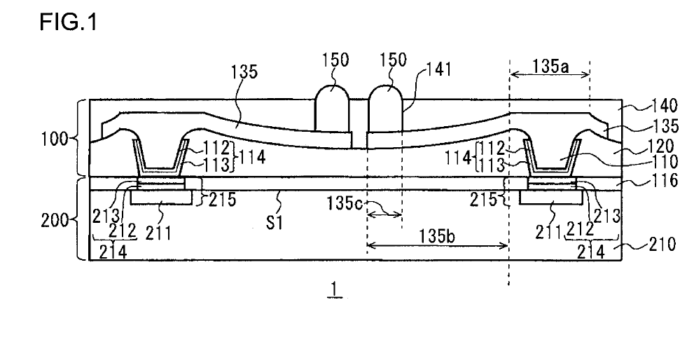

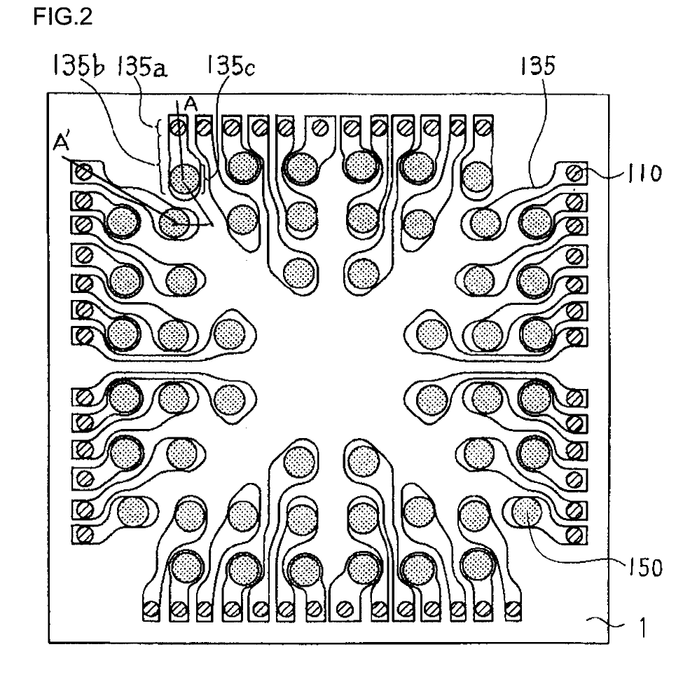

FIG. 1 is a schematic cross-sectional view showing a structure of a semiconductor device to a first embodiment of the present invention. FIG. 2 is a plan view showing a structure of a semiconductor module which corresponds to a single chip. FIG. 1 is a cross-sectional view taken along the line A-A′ of FIG. 2.

A semiconductor module 1 includes a device mounting board 100 and a semiconductor device 200.

The device mounting board 100 includes an insulating resin layer 120, a wiring layer 135 (rewiring) provided on one main surface of the insulating resin layer 120, and a bump electrode 110, electrically connected to the wiring layer 135, which is protruded from the wiring layer 135 toward an insulating resin layer 120 side. In the semiconductor mounting board 100, the bump electrode 110 is formed in an electrode forming region 135a of the wiring layer 135 along each side of the semiconductor module 1.

The insulating resin layer 120 plays a role of an adhesion layer provided between the wiring layer 135 and the semiconductor device 200. The insulating resin layer 120 is formed of an insulating material that develops hardening when heated, an insulating material that develops plasticity when heated, an insulating material that becomes deformed when heated or the like. The thickness of the insulating resin layer 120 is about 20 μm, for instance.

The insulating resin layer 120 may be formed of a thermosetting resin such as a melamine derivative (e.g., BT resin), liquid-crystal polymer, PPE resin, fluorine resin, phenol resin, epoxy resin or polyamide bismaleimide, or the like.

An example of the insulating material that develops plasticity when heated is a thermoplastic resin such as acrylic thermoplastic resin. The temperature at which plasticity develops is in the range of 150° C. to 200° C., for instance.

An example of the insulating material that becomes deformed when heated is a thermosetting resin whose glass transition temperature (Tg) is in the range of 80 to 130° C., for instance. An example of such a thermosetting resin is polyimide-series thermosetting resin.

The wiring layer 135 is provided on the main surface of the insulating resin layer 120 on a side thereof opposite to the semiconductor device 200, and is formed of a conducive material, preferably a rolled metal or more preferably a rolled copper. Such rolled copper performs excellently as a material for rewiring because it has greater mechanical strength than a copper-made metallic film formed by plating or the like. Note that the wiring layer 135 may be formed of electrolyte copper or the like. The wiring layer has an electrode forming region 135a where the bump electrode 110 is formed, a wiring region 135b extending from the electrode forming region 135a, and an external connection region 135c disposed on an end of wiring region which is an opposite side to the electrode forming region 135a. A solder ball 150 described later is disposed in the external connection region 135c. The thickness of the wiring layer 135 is about 15 μm, for instance.

In the electrode forming region 135a, the bump electrode 110 is protruded from the wiring layer 135, and the bump electrode 110 penetrates the insulating resin layer 120 and reaches the semiconductor device 200. The electrode forming region (the bump electrode 110) is formed in a position corresponding to a device electrode 211 of the semiconductor device 210, and the bump electrode 110 and the device electrode 211 are electrically coupled to each other. In the present embodiment, the wiring layer 135 and the bump electrode 110 is formed integrally with each other. This structure assures the connection between the wiring layer 135 and the bump electrode 110. Also, such a structure, in which the wiring layer 135 and the bump electrode 110 is formed integrally with each other, can prevent the occurrence of cracks or the like due to the heat stress occurring at an interface between the wiring layer 135 and the bump electrode 110 in a usage environment of the semiconductor module 1. Moreover, the wiring layer 135 and the device electrode 211 are electrically connected simultaneously when the bump electrode 110 and the device electrode 211 are press-bonded together, and therefore an advantageous effect of not increasing the number of processes is achieved.

The overall shape of the bump electrode 110 protruding from the wiring 135 on an insulating resin layer 120 side is such that the bump electrode 110 grows smaller in diameter toward the tip part thereof. Though the planar view of the bump electrode 110 is an approximately round shape including the shape of an ellipse, the shape of the bump electrode 110 is not particularly limited to this shape and may be polygonal, such as quadrangular, instead. A metallic layer 114 is stacked on a top surface and a side surface of the bump electrode 110. The metallic layer 114 includes an Ni layer 112 made of nickel (Ni), which is disposed in contact with the bump electrode 110, and an Au layer 113 made of gold (Au) stacked on the Ni layer 112 wherein the Ni layer 112 and the Au layer 113 are stacked, in this order, from the bump electrode 110 side.

The Au layer 113 is stacked on the outermost surface of the metallic layer 114, whereas an Au layer 213 is stacked on the outermost surface of a metallic layer 214. Accordingly, the bump electrode 110 and the device electrode 211 are bonded to each other through Au—Au bonding (bonding between Au and Au) and thereby they are electrically connected to each other. Hence, the connection reliability between the bump electrode 110 and the device electrode 211 is improved. The metallic layer 214 is stacked on the device electrode 211. The metallic layer 214 includes a Ni layer 212 formed of nickel (Ni) in contact with the device electrode 211 and an Au layer 213 formed of gold (Au) stacked on the Ni layer 212 wherein the Ni layer 212 and the Au layer 213 are stacked, in this order, on a device electrode 211 side. Note that the bump electrode 110 and the device electrode 211 may be directly connected to each other without having the metallic layers 114 and 214 interposed therebetween or may be connected to each other with a low-melting-point conductive material such as solder interposed therebetween. The height of the bump electrode 110, the diameter of top surface thereof and the diameter of bottom surface thereof are about 20 μm, about 45 μmφ and about 60 μmφ, respectively. The thickness of Ni layers 112 and 212 and the thickness of Au layer 113 and 213 are about 1 μm to 15 μm, and about 0.03 μm to about 1 μm, respectively.

A wiring protective layer 140 is provided on the wiring layer 135 and the insulating resin layer 120 (on top of FIG. 1). This wiring protective layer 140 protects the wiring layer 135 against oxidation or the like. The wiring protective layer 140 may be a photo solder resist (PSR) layer, for instance. An opening 141 is formed in a predetermined position of the wiring protective layer 140, and the external connection region 135c of the wiring layer 135 is exposed by the opening 141. The solder ball 150, which functions as an external connection electrode, is formed within the opening 141. And the solder ball 150 and the wiring layer 135 are electrically connected to each other. The position in which the solder ball 150 is formed, namely, the area in which the opening 141 is formed is, for instance, an end where circuit wiring is extended through a rewiring, and is located approximately in the center of the wiring protective layer 140. The thickness of the wiring protective layer 140 is about 25 μm, for instance.

The semiconductor 200 includes a semiconductor substrate 210, a device electrode 211, a metallic layer 214, and a device protective layer 115.

The semiconductor substrate 210 is a P-type silicon wafer. An integrated circuit (IC), a large-scale integrated circuit (LSI) (not shown) or the like is formed, using a known technology, on a main surface S1 side (top side of FIG. 1) of the semiconductor substrate 210.

The device electrode connected to the integrated circuit is provided on the main surface S1 which is a packaging surface. The device electrode 211 is made of a metal such as aluminum (Al) or copper (Cu). The metallic layer 214 is stacked on the surface of the device electrode 211. The metallic layer 214 includes the Ni layer 212, formed of nickel (Ni), in contact with the device electrode 211 and the Au layer 213 formed of gold (Au) stacked on the Ni layer 212.

On the main surface S1 of the semiconductor device 210, the device protective layer 115 is provided such that the device electrode 211 is exposed thereon. Note that the device electrode 211 together with the metallic layer 214 are referred to as “device-side electrode 215”. As the device protective layer 115, a silicon dioxide (SiO₂) film, a silicon nitride (SiN) film, a polyimide (PI) film or the like is preferably employed. The device protective layer 115 according to the present embodiment is comprised of the silicon nitride film in contact with the semiconductor substrate 210 and the polyimide film stacked on said silicon nitride film. Note that in FIG. 1 these two films (silicon nitride film and polyimide film) are denoted as a single layer by the reference numeral 116.

A method for manufacturing a semiconductor module according to the present embodiment is now described.

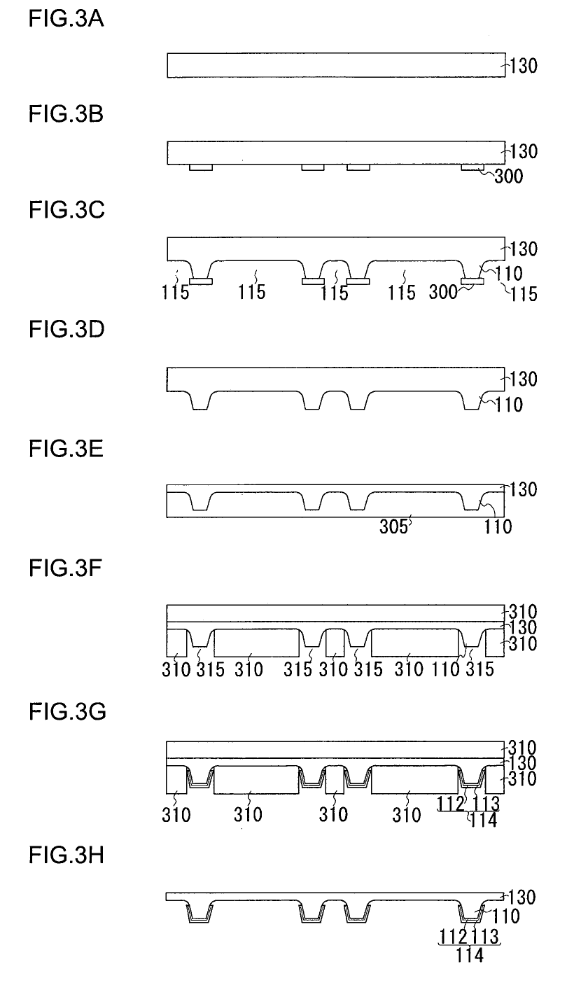

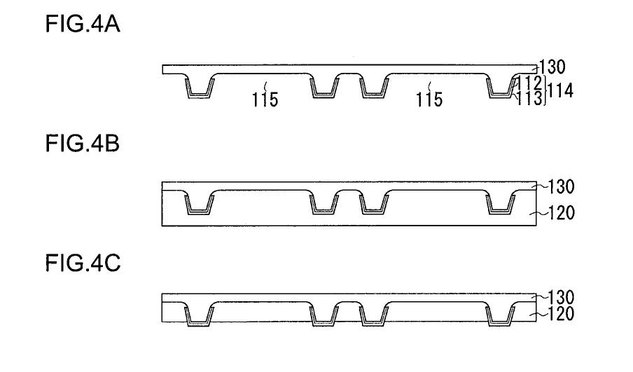

FIGS. 3A to 3H and FIGS. 4A to 4C are cross-sectional views showing a process in a method for making a semiconductor module according to a first embodiment of the present invention.

As illustrated in FIG. 3A, a copper sheet 130 is first prepared as a metallic sheet having a thickness greater than at least the sum of the height of the bump electrode 110 and the thickness of the wiring layer 135. The thickness of the copper sheet 130 is 125 μm, for instance. The rolled metal used for the copper sheet 130 is a rolled copper.

Then, as shown in FIG. 3B, resists 300 are formed selectively in alignment with a pattern that corresponds to a predetermined formation region of bump electrodes using a lithography method. More specifically, a resist film of predetermined film thickness is laminated onto the copper sheet 130 by a laminator apparatus, and it is then subjected to exposure using a photo mask having the pattern of bump electrodes 110. After this, the resists 300 are selectively formed on the copper sheet 130 by a development. To improve the adhesion of the resists 300 to the copper sheet 300, it is desirable that a pretreatment, such as grinding, cleaning and the like, be performed as necessary on the surface of the copper sheet 130 before the lamination of the resist film 300 thereon. To protect the copper sheet 130, it is desirable that a resist protective film (not shown) is formed on the entire surface (top side) opposite to the surface on which the resists 300 have been provided.

Then, as shown in FIG. 3C, using the resists 300 as a mask, the bump electrodes 110 of a predetermined circular truncated cone pattern (trapezoidal in cross section where the cone-shaped tip end is removed) protruding from the surface of the copper sheet 130 is formed by performing a wet etching on the copper sheet 300, in which a chemical such as ferric chloride solution or the like is used. In other words, a recess 115 is formed between the bump electrodes 110 by the wet-etching of the copper sheet 130. In this case, the bump electrode 110 is formed such that the bump electrode 110 has a tapered side surface whose diameter (dimension) decreases as the side surface of the bump electrode 110 approaches the tip end thereof. The wet etching is performed such that the diameter (width) of the top of the bump electrode 110 is narrower than the width of the device electrode 211 corresponding to the bump electrode 11. The diameter of the base, the diameter of the top, and the height of the bump electrode 110 according to the present embodiment are about 60 μmφ, about 45 μmφ, and about 20 μmφ, respectively.

Then, as shown in FIG. 3D, the resists 300 and the resist protective film are removed using a stripping agent.

The bump electrodes 110 are integrally formed on the copper sheet 130 through a process as described above. It is to be noted that a metal mask of silver (Ag) may be used instead of the resist 300. In such a case, etch selectivity in relation to the copper sheet 130 can be amply secured, so that finer patterning of the bump electrodes 110 can be realized.

Then, as shown in FIG. 3E, the surface of the copper sheet 130 in a side opposite to the side where the bump electrodes 110 are provided is etched back using a chemical such as ferric chloride solution or the like and the copper sheet 130 is turned into thin film thereby. At this time, a resist protective film 305 is formed on a side of the copper sheet 130 where the bump electrodes 110 are provided, to protect the bump electrodes 110 and the copper sheet 130. After the etching processing, the resist protective film 305 is removed. As a result, formed is a copper sheet 130 which is so processed as to have a predetermined thickness (thickness of the wiring 135) and with which predetermined bump electrodes 110 are provided integrally. The thickness of the copper sheet 130 according to the present embodiment is about 15 μm.

Then, as shown in FIG. 3F, resists 310 having a plating resistance is stacked, on one main surface of the copper sheet 130 which is the side having the bump electrodes 110, in such a manner that the bump electrodes 110 are submerged among the resists 310. Then openings 315 are formed, using a lithography method, in such a manner that the bump electrodes 110 are exposed. To protect the copper sheet 130, it is desirable that a resist protective film 310 is also formed on the entire surface (top side) opposite to the surface on which the resists 310 have been provided.

Then, as shown in FIG. 3G, the resists 310 are used as a mask, and a metallic layer 114 is formed to cover the top surface of the bump electrode 110 exposed from the opening 315 and to cover approximately one half the height of the side surface thereof by electrolytic plating or electroless plating, for instance. For example, the metallic layer 114 is formed such that a Ni layer 112 is first formed on the top surface and the side surface (the side surface covering about ½ of the height of the bump electrode 110) of the bump electrode 110 and then an Au layer 113 is formed on the Ni layer 112. Note that a region where the metallic layer 114 is to be formed may be the top surface thereof only. In such a case, the openings 315, which is of a size such that the surface of the bump electrode 110 can be exposed, are formed in the resists 310.

Then, as shown in FIG. 3H, the resists 70 are removed, using the stripping agent, after the formation of the metallic layers 114. Thus, formed is the copper sheet 130, formed integrally with the wiring layer 135, in which the tip end thereof is covered with the metallic layer 114.

Then, as shown in FIG. 4A, the copper sheet 130 formed in the process shown in FIG. 3H is prepared.

Then, as shown in FIG. 4B, an insulating resin layer 120 is stacked on the surface of the copper sheet 130 on the side where the bump electrodes 110 are provided, using a vacuum laminating method, in such a manner that the bump electrodes 110 are submerged in the insulating resin layer 120. As described above, an insulating material that develops plasticity or becomes deformed when pressurized or heated is used as the insulating resin layer 120.

Then, as shown in FIG. 4C, the insulating resin layer 12 is turned into thin film by the use of O₂ plasma etching so that at least the top surface of the bump electrode 110 is exposed. Also, part of the side surface of the bump electrode 110 in addition to the top surface thereof may be exposed. In other words, it suffices if part of the bump electrode 110 including the metallic layer 114 is exposed so that the volume of the insulating resin layer 120 filled into the recess 115 becomes smaller than that of the recess 115 formed by wet-etching the copper sheet 130 in the above-described process. The amount of insulating resin layer may be adjusted so that no cavity (void) is created when the insulating resin layer and the copper sheet are press-bonded together in a subsequent process.

As described above, a device mounting board 100 can be formed where the device protective film 140 and the solder balls 150 are not formed.

A description is next given of a process of connecting the device mounting board 100, formed in the above description in conjunction with FIG. 4C, and the semiconductor device.

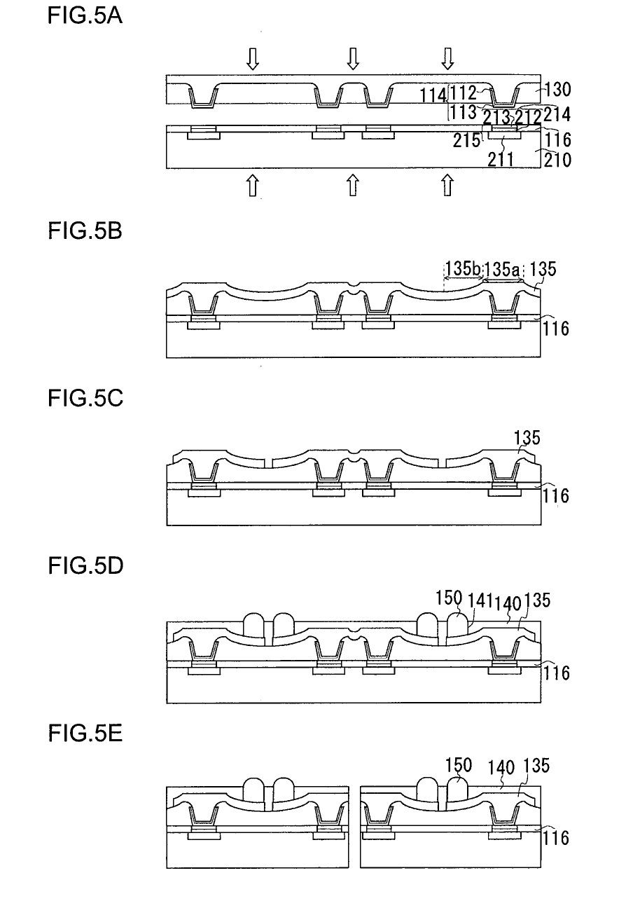

As shown in FIG. 5A, prepared is a semiconductor substrate 210 (semiconductor wafer) comprised of device-side electrodes 215 and device protective layer 113 on a main surface S1 side. Then the semiconductor substrate 210 and the copper sheet 130 formed integrally with the bump electrodes 110 are placed between a pair of flat plates (not shown) constituting a press machine. Then the semiconductor substrate 210 and the copper sheet 130 are heated, press-bonded and finally electrically coupled with each other by the use of the press machine, in a state where a metallic layer 214 and a device-side electrode 215 both covering a corresponding bump electrode 110 are abutted against each other. The pressure and temperature under which the semiconductor substrate 210 and the copper sheet 130 are press-formed are about 1 MP and about 200° C., respectively.

A predetermined integrated circuit is formed in the semiconductor substrate 210, such as a P-type silicon substrate, and the device electrodes 211 are formed in the outer periphery of the integrated circuit by the use of a semiconductor manufacturing process that combines known techniques including lithography, etching, ion implantation, film formation and thermal processing. Then a silicon nitride film is formed on the main surface S1 of the semiconductor substrate 210 using a CVD method, for instance, and for example a polyimide film is applied to the nitride film and hardened so as to form a laminated device protective layer 115. The device protective layer 115 is etched so that the device electrodes 211 can be exposed. There is provided a structure where the metallic layer 214 comprised of the Ni layer 212 layer 212 and the Au layer 213 is stacked on the device electrode 211 by electrolytic plating or electroless plating.

A description is now given of how the press-bonding is performed from the start to the end thereof.

As the pressurizing is applied by the press machine, the contact between the metallic layer 114 of the bump electrode 110 and the metallic layer 214 of the semiconductor device 210 is first secured and completed. At this time, the insulating resin layer 120 which is thinner than the bump electrode 110 has not yet come in contact with the metallic layer 214 and the device protective layer 113.

As the pressurizing continues further, the wiring region 135b of the copper sheet 130 excepting the electrode forming region 135a (bump electrode 110 portion) is warped to protrude toward the semiconductor device 210. Thus the insulating resin layer 120 is pressurized toward the semiconductor device 210, and finally comes in contact with the metallic layer 214 and the device protective layer 115 as shown in FIG. 5B.

As described above, the metallic layer 114 of the bump electrode 110 and the metallic layer 214 of the semiconductor device 210 are first connected to each other and then the insulating resin layer 120 is adhered to the metallic layer 214 and the device protective layer 115. Thus the metallic layer 114 thereof and the metallic layer 215 thereof can be reliably connected electrically to each other without the insulating resin layer 120 entering between the bump electrode 110 and the device-side electrode 215.

In a case where a conventional-type recess 115 is filled with the insulating resin layer having the volume greater than or equal to that of the conventional-type recess 115, the insulating resin layer 120 flows into space between the bump electrode 110 and the device-side electrode 215 when pressurized. According to the present embodiment, on the other hand, the amount of insulating resin layer within the recess is set to an amount less than that calculated from the height of the bump electrode 110. As a result, the metallic layer 114 and the metallic layer 214 are first connected, which is followed by the adhesion of the insulating resin layer 120 and the semiconductor device 210. Accordingly, the medium of the insulating resin layer 120 remaining between the metallic layer 114 and the metallic layer 214 can be prevented and therefore the electrical connection can be assured. Also, since the amount of insulating resin layer is small, pressing the wiring layer 135 allows the wiring layer 135 to warp to protrude toward the semiconductor device 210. Thus, even though the amount of insulating resin layer is reduced, the metallic layer 214 and the device protective layer 115 can be reliably adhered to the insulating resin layer 120.

Moreover, when the copper sheet 130 is pressurized in the wiring region 135b excepting the bump electrode 110 portion, the wiring region 135 of the copper sheet 130 is warped to protrude toward the semiconductor device 210 and the pressure is transferred to the insulating resin layer 120. Hence, in the recess 115, no space is created which is not filled with the insulating resin layer 120. Such a structure achieved by employing the present embodiment eliminates the following problems. That is, the problems meant here include, for example, a case where a space is created and water enters into the space in a subsequence manufacturing process or after the semiconductor module has been mounted to a product and a case where the space expands due to heat and the expanded space causes a faulty electrical connection between the bump electrode 110 and the device-side electrode 215. The present embodiment eliminates such problems.

Note that a top surface in a certain part of the bump electrode 110 becomes enlarged when pressurized and therefore the contact area thereof increases. Such a shape having an enlarged top surface assures the electrical connection between the bump electrode 110 and the device-side electrode 215.

Next, as shown in FIG. 5C, a wiring (rewiring) 135 is formed by processing the copper sheet 130 into a predetermined pattern using a lithography and etching technique. More specifically, a wiring layer 135 is formed, by etching a predetermined region of the copper sheet 130, into a pattern as shown in FIG. 2 using a chemical such ferric chloride solution.

As shown in FIG. 5D, a protective layer (photo solder resist layer) 140 is laminated on the wiring layer 135 and the insulating resin layer 120 and then openings 141 are provided in predetermined regions (solder ball mounting regions) of the protective layer 140 using a photolithography method. The protective layer 140 functions as a protective film for the wiring layer 135. Epoxy resin or the like is used for the protective layer 140, and the film thickness of the protective layer 140 is about 20 μm. Then the solder balls 150 are mounted in the openings 141 by using a screen printing method. More specifically, the solder balls 150 are formed by printing soldering paste, which is a pasty mixture of resin and solder material, in desired positions through a screen mask and then heating the printed paste to a solder melting temperature.

Then, as shown in FIG. 5E, a semiconductor wafer is diced into individual modules by a dicing apparatus or the like, thereby completing the production of semiconductor modules.

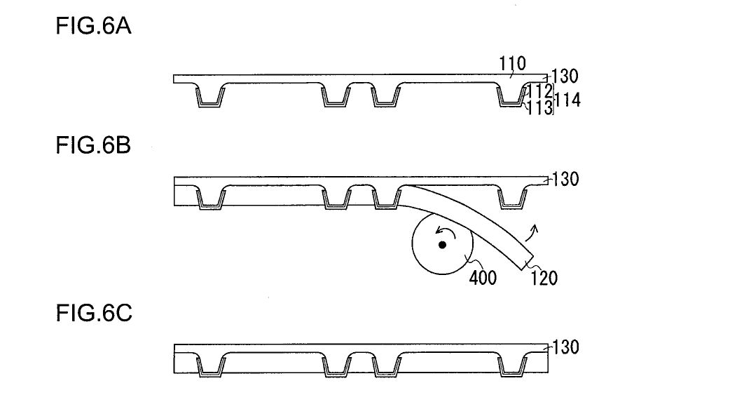

Another method for forming the insulating resin layer 120 in the recess 115 described in the above embodiment is now described with reference to FIGS. 6A to 6C. A process shown in FIGS. 6A to 6C is another method corresponding to the process shown in FIGS. 4A to 4C. As for the other procedures taken in this method but not shown in FIGS. 6A to 6C, the semiconductor module can be obtained through the above-described processes.

As shown in FIG. 6A, prepared first is the copper sheet 130, formed in the process shown in FIG. 3H, where the metallic layer 114 is provided on the top surface and part of the side surface of the bump electrode 110.

Then, as shown in FIG. 6B, the insulating resin layer 120 in the form of a film is adhered to the copper sheet 130 by pressing it by a roller 400. In so doing, the thickness of the insulating resin layer 120 in the form of a film is either set to the thickness such that the top surface of the bump electrode 110 is exposed or the thickness such that part of the side surface thereof is exposed. By using the insulating resin layer 120 having such a thickness, the insulating resin layer 120 whose thickness is smaller than the thickness (height) of the bump electrode 110 is formed as shown in FIG. 6C.

In this method, the predetermined thickness thereof is one such that the bump electrode 110 is exposed. Thus, no additional process for adjusting the thickness by the use of oxygen plasma etching or the like is required. As a result, the manufacturing processes are simplified and therefore the cost is reduced. Note that a plate laminating method may be used instead of the aforementioned roll laminating method using the roller.

In the above-described embodiment, the metallic layer 214 is formed such that the top surface of the metallic layer 214 is coplanar with the top surface of the device protective film 115. Thus, even if the bump electrode 110 and the metallic layer 214 are dislocated to each other in the horizontal direction by a small amount, the contact area may decrease but a faulty connection will not occur because the top surface of metallic layer 214 is coplanar with the top surface of the device protective film 115.

Also, in the above-described embodiment, in order to reduce the thickness of the copper sheet 130, a process for thinning the copper sheet 130 by performing the etching from the back side is carried out (See FIG. 4C) before the resin forming process. By thinning the copper sheet 130 in said process, the following advantageous effect is achieved. That is, the warping due to the thermal stress can be reduced in a subsequent process for press-bonding the copper sheet and the semiconductor device (FIGS. 5A and 5B). A process for thinning the copper sheet 130 according to the present embodiment is not limited to said particular process and, for example, it may be carried out after the process of FIG. 5A. In such a case, the handling of the copper sheet 130 in a process before said process becomes easier. Shown in the above-described embodiment is an example where the metallic layer 114 comprised of the Ni layer 112 and the Au layer 113 is formed on a bump portion (bump electrode 110) and the insulating resin layer 120 is thinned such that the metallic layer 114 is partially exposed. The same advantageous effect as this embodiment can be achieved even if no metallic layer 114 is formed on the top surface and the side surface of the bump portion (bump electrode 110) and the insulating resin layer 120 is thinned such that the bump portion (bump electrode 110) is partially exposed. The process for thinning the insulating resin layer 120 in such a manner that the bump portion (bump electrode 110) is partially exposed can be achieved, similarly to FIGS. 4A to 4C, after the copper sheet 130 has been etched back in the aforementioned process of FIG. 3E. In this case, assume that the metallic layer 114 is not formed in FIGS. 4A to 4C.

While the preferred embodiments of the present invention and their modifications have been described using specific terms, such description is for illustrative purposes only, and it is to be understood that changes and variations may further be made without departing from the spirit or scope of the appended claims.

What is claimed is:

1. A method for manufacturing a semiconductor module, the method comprising:
a first process of forming a protrusion by etching a metallic sheet;
a second process of forming an insulating layer having a thickness such that the protrusion is partially exposed; and
a third process of press-bonding a semiconductor substrate, having a plurality of electrodes on the surface thereof, and the metallic sheet via the insulating layer and electrically connecting the protrusion to the electrode.

2. A method, for manufacturing a semiconductor module, according to claim 1, wherein in said second process, the insulating layer having the thickness greater than the height of the protrusion is formed and then the insulating layer is etched to have such a thickness that the protrusion is partially exposed.

3. A method, for manufacturing a semiconductor module, according to claim 1, wherein the insulating layer is formed by laminating an insulating resin film or a plurality of insulating films stacked.

4. A method, for manufacturing a semiconductor module, according to claim 1, further comprising, between said first process and said second process, a process of etching a surface of the metallic sheet, the surface thereof being one opposite to the surface on which the protrusion is formed.

5. A method for manufacturing a semiconductor module, the method comprising:
a first process of forming a protrusion by etching a metallic sheet;
a second process of forming a metallic layer on a top surface of the protrusion and forming an insulating layer having a thickness such that the metallic layer is partially exposed; and
a third process of press-bonding a semiconductor substrate, having a plurality of electrodes on the surface thereof, and the metallic sheet via the insulating layer and electrically connecting the protrusion to the electrode.

6. A method, for manufacturing a semiconductor module, according to claim 5, wherein in said second process, the insulating layer having the thickness greater than the sum of the thickness of the metallic layer and the height of the protrusion is formed and then the insulating layer is etched to have such a thickness that the protrusion is partially exposed.

7. A method, for manufacturing a semiconductor module, according to claim 5, wherein the insulating layer is formed by laminating an insulating resin film or a plurality of insulating films stacked.

8. A method, for manufacturing a semiconductor module, according to claim 5, further comprising, between said first process and said second process, a process of etching a surface of the metallic sheet, the surface thereof being one opposite to the surface on which the protrusion is formed.
